(19) United States
(12) Patent Application Publication
(10) Pub. No.: US 2014/0367077 A1
(43) Pub. Date: Dec. 18, 2014

(54) COMPLEX HEAT DISSIPATION ASSEMBLY

(71) Applicant: CHE YUAN WU, New Taipei City (TW)

(72) Inventor: CHE YUAN WU, New Taipei City (TW)

(21) Appl. No.: 14/023,649

(22) Filed: Sep. 11, 2013

(30) Foreign Application Priority Data
Jun. 17, 2013 (TW) 102211257

(51) Int. Cl. H05K 7/20

(52) U.S. Cl. CPC H05K 7/2039
USPC 165/185

(57) ABSTRACT

A complex heat dissipation assembly, which includes: a heat conduction plate assembly composed of multiple electroconductive heat conduction plates, the heat conduction plate assembly having a contact face in contact with the heat source; and a heat spreader assembly composed of multiple heat spreaders, which are able to quickly transversely conduct heat. The heat spreaders are disposed between the heat conduction plates in contact therewith. Each heat spreader has a proximal-to-heat-source section and a distal-from-heat-source section. The heat conduction plate assembly and the heat spreader assembly cooperate with each other to complexly conduct and spread the heat of the heat source in different directions so as to uniformly and quickly dissipate the heat. Accordingly, the heat is prevented from accumulating around the heat source. In this case, the temperature will not locally abnormally rise.

### BACKGROUND OF THE INVENTION

1. Field of the Invention

The present invention relates generally to a complex heat dissipation assembly, and more particularly to a low-cost and simplified heat dissipation structure, which is able to quickly and uniformly dissipate the heat generated by a heat source so as to avoid accumulation of the heat around a local section.

2. Description of the Related Art

In recent years, various electronic products are more and more widely used. The electronic products employ all kinds of operation analytic and power amplification electronic components (such as central processor, light-emitting elements, power transistors and the like components) to provide complicated and sophisticated video/audio effect in operation. In use of the electronic products, the electronic components will inevitably generate a great amount of heat. In the case that the heat is not efficiently dissipated, the heat will accumulate around the heat source to cause overheating of a local part of the surface of the case. Conventionally, a heat conduction member (such as a heat pipe) with better thermal conductivity is generally used to partially The electronic products include all kinds of electronic components (such as central processor, light-emitting elements, power transistors and the like components) to provide complicated and sophisticated video/audio effect in operation. In use of the electronic products, the electronic components will inevitably generate a great amount of heat. In the case that the heat is not efficiently dissipated, the heat will accumulate around the heat source to cause overheating of a local part of the surface of the case. Conventionally, a heat conduction member (such as a heat pipe) with better thermal conductivity is generally used to partially contact the heat source. In addition, a heat dissipation assembly (such as a radiating fin assembly and cooling fan) are disposed on the heat conduction member. The heat conduction member can transfer the heat of the heat source to the heat dissipation assembly to dissipate the heat. In this case, the heat is prevented from concentrating so that the abnormal rise of the temperature of a local section can be avoided.

However, the heat conduction member (heat pipe) and the heat dissipation assembly (radiating fin assembly and cooling fan) have a considerably complicated structure and are manufactured at quite high cost. Therefore, it is uneconomic to apply these components to the electronic products.

It is therefore tried by the applicant to provide a complex heat dissipation assembly device to overcome the above problems. The complex heat dissipation assembly has simple structure and is manufactured at lower cost and is able to quickly and uniformly dissipate the heat generated by a heat source so as to avoid concentration of the heat and abnormal rise of the temperature of a local section.

### SUMMARY OF THE INVENTION

It is therefore a primary object of the present invention to provide a complex heat dissipation assembly, which is able to quickly transfer heat generated by a heat source from the heat source and dissipate the heat outward so as to avoid concentration of the heat around the heat source. In this case, the temperature will not locally abnormally rise.

It is a further object of the present invention to provide the above complex heat dissipation assembly, which is able to achieve excellent heat dissipation effect without using expensive heat conduction component. Therefore, the manufacturing cost is lowered to promote the economic efficiency.

To achieve the above and other objects, the complex heat dissipation assembly of the present invention includes: a heat conduction plate assembly composed of multiple stacked electroconductive heat conduction plates; and a heat spreader assembly composed of multiple heat spreaders, which are able to quickly conduct heat along the surface. The heat spreaders are alternately disposed between the heat conduction plates. Each of the heat spreaders has a proximal-to-heat-source section proximal to a heat source and a distal-from-heat-source section extending in a direction away from the heat source. At least one of the heat conduction plate assembly and the heat spreader assembly is in contact with the heat source.

In the above complex heat dissipation assembly, each heat conduction plate has a heat spreader in adjacency to and corresponding to the heat conduction plate. The heat spreader is disposed on one face of the adjacent and corresponding heat conduction plate, which face is proximal to the heat source.

In the above complex heat dissipation assembly, both the heat conduction plate assembly and the heat spreader assembly are in contact with the heat source.

In the above complex heat dissipation assembly, the heat-conducting adhesive is disposed between at least one of the heat conduction plate assembly and the heat spreader assembly and the heat source.

In the above complex heat dissipation assembly, each heat conduction plate has a heat spreader in adjacency to and corresponding to the heat conduction plate. The heat spreader is disposed on one face of the adjacent and corresponding heat conduction plate, which face is distal from the heat source.

In the above complex heat dissipation assembly, the heat conduction plate assembly is in contact with the heat source and the heat-conducting adhesive is disposed between the heat conduction plate assembly and the heat source.

In the above complex heat dissipation assembly, the heat spreaders have an area smaller than that of the heat conduction plate in contact with the heat spreaders.

In the above complex heat dissipation assembly, the heat spreaders are elongated plate bodies.

In the above complex heat dissipation assembly, each of the heat spreaders has an elongated main extension section and at least one branch section obliquely extending from one side of the main extension section.

In the above complex heat dissipation assembly, the branch section obliquely extends in a direction away from the heat source and the main extension section.

In the above complex heat dissipation assembly, each of the heat spreaders has an elongated main extension section and at least one branch section obliquely extending from each of two sides of the main extension section.

In the above complex heat dissipation assembly, the branch section obliquely extends in a direction away from the heat source and the main extension section.

In the above complex heat dissipation assembly, the heat spreaders have an area equal to that of the heat conduction plate in contact with the heat spreaders.

In the above complex heat dissipation assembly, heat-conducting electroconductive adhesive layers are respectively disposed between the heat conduction plates and the heat spreaders.

In the above complex heat dissipation assembly, the heat conduction plate assembly is composed of multiple heat conduction plates with the same size and shape.

The present invention can be best understood through the following description and accompanying drawings, wherein:

### BRIEF DESCRIPTION OF THE DRAWINGS

FIG. 1 is a perspective exploded view of a first embodiment of the present invention;

FIG. 2A is a perspective exploded view of a second embodiment of the present invention;

FIG. 2B is a perspective assembled view of the second embodiment of the present invention, showing the application thereof;

FIG. 3 is a sectional assembled view of the second embodiment of the present invention;

FIG. 4 is a perspective exploded view of a third embodiment of the present invention;

FIG. 5 is a perspective assembled view of the third embodiment of the present invention, showing the application thereof;

FIG. 6 is a perspective exploded view of a fourth embodiment of the present invention; and

FIG. 7 is a perspective assembled view of the fourth embodiment of the present invention, showing the application thereof.

### DETAILED DESCRIPTION OF THE PREFERRED EMBODIMENTS

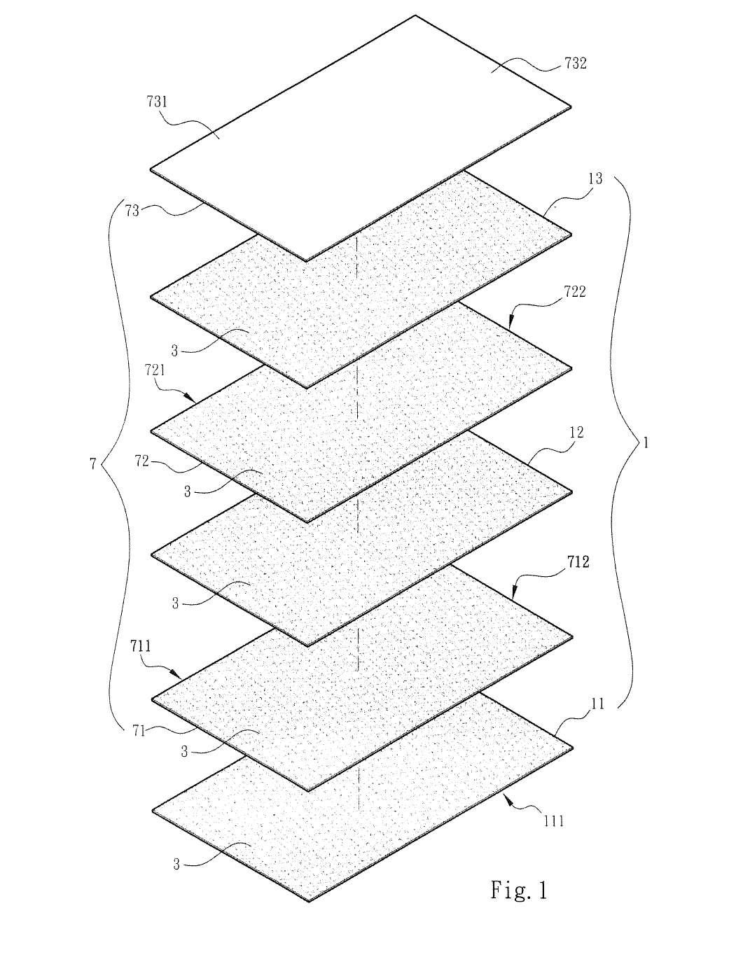

Please refer to FIG. 1. According to a first embodiment, the complex heat dissipation assembly of the present invention includes a heat conduction plate assembly 1 and a heat spreader assembly 7. The heat conduction plate assembly 1 is composed of multiple sequentially stacked electroconductive heat conduction plates 11, 12, 13, (which can be made of metal material). The outermost surface of the heat conduction plate assembly 1 is defined as a contact face 111. The heat spreader assembly 7 is composed of multiple heat spreaders 71, 72, 73 respectively alternately disposed between the heat conduction plates 11, 12, 13. The heat spreaders 71, 72, 73 are plate-shaped structure bodies with an area equal to that of the heat conduction plates 11, 12, 13. The heat spreaders 71, 72, 73 can be made of graphite or the like material. The heat spreaders 71, 72, 73 have a property of quickly conducting heat along the surface (transversely). In this embodiment, each of the heat spreaders 71, 72, 73 has a proximal-to-heat-source section 711, 721, 731 and a distal-from-heat-source section 712, 722, 732. The heat spreaders 71, 72, 73 and the heat conduction plates 11, 12, 13 are electrically bonded to each other by means of heat-conducting electroconductive adhesive layers 3.

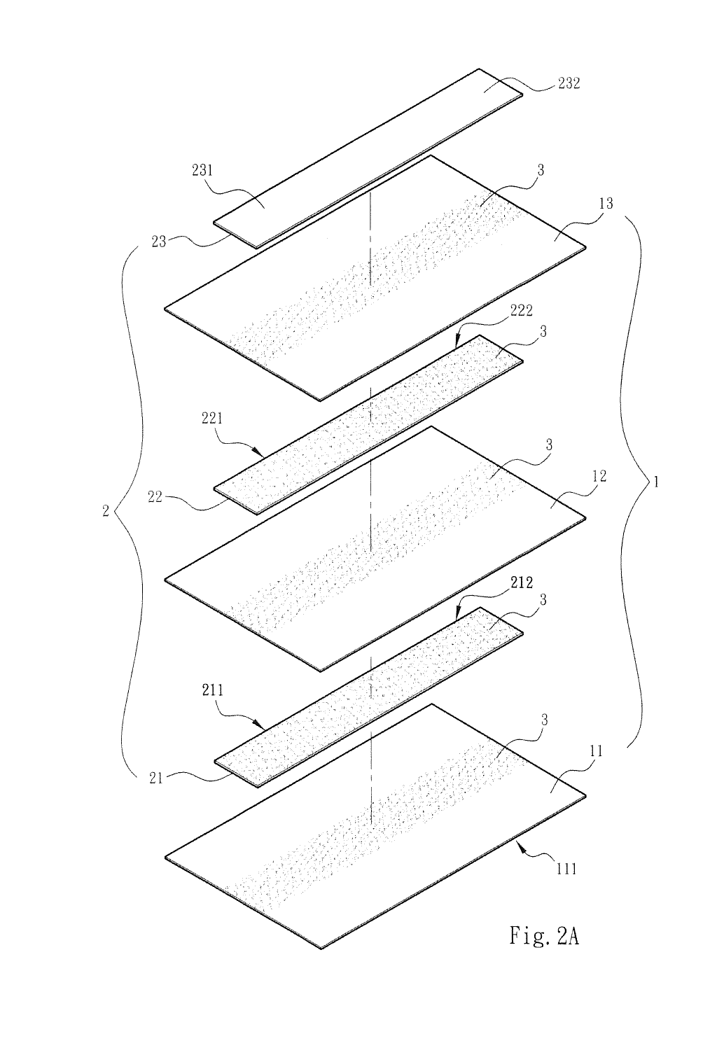

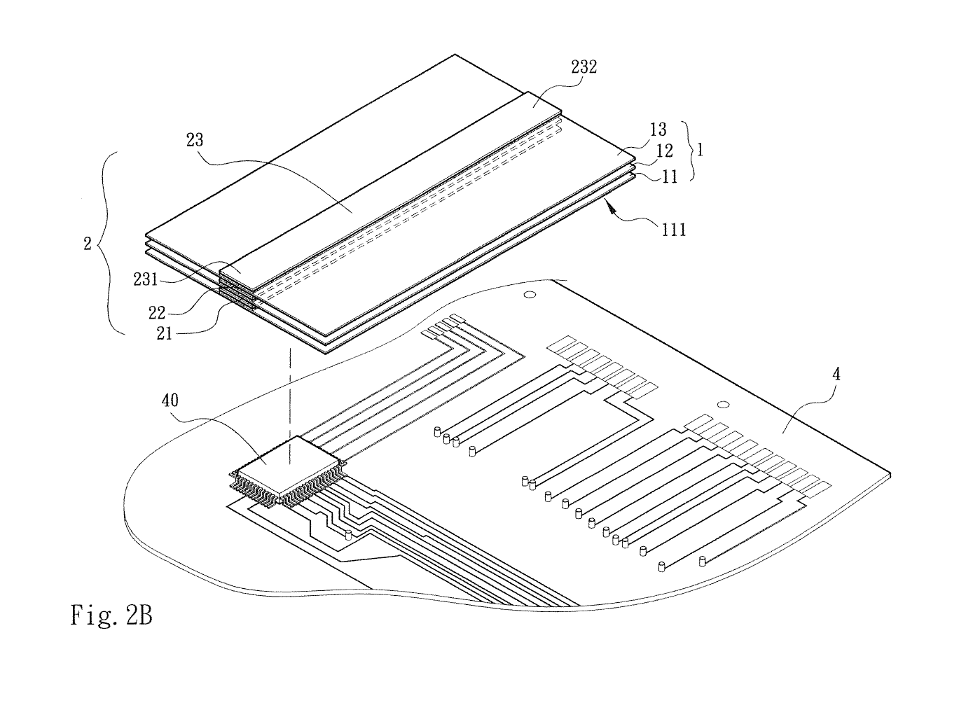

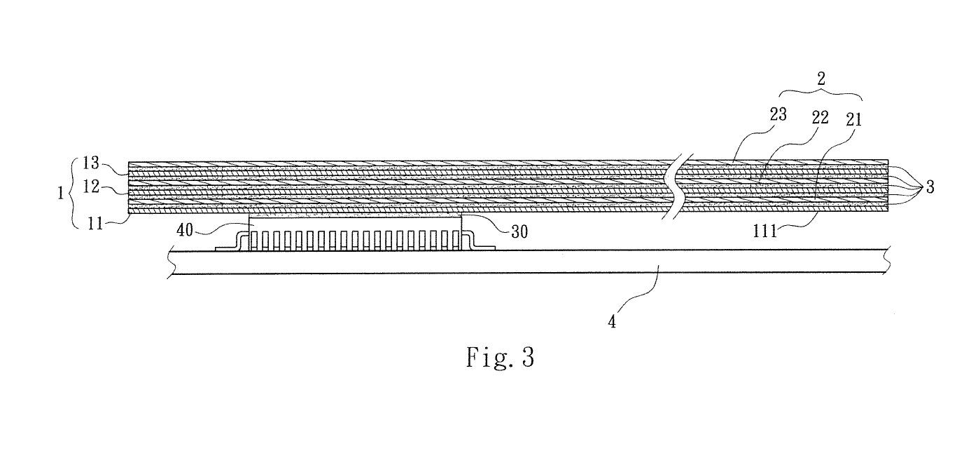

Please refer to FIGS. 2A, 2B and 3. According to a second embodiment, the complex heat dissipation assembly of the present invention includes a heat conduction plate assembly 1 and a heat spreader assembly 2. The heat conduction plate assembly 1 is composed of multiple sequentially stacked electroconductive heat conduction plates 11, 12, 13, (which can be made of metal material). The outermost surface of the heat conduction plate assembly 1 is defined as a contact face 111. The heat spreader assembly 2 is composed of multiple heat spreaders 21, 22, 23 respectively alternately disposed between the heat conduction plates 11, 12, 13. The heat spreaders 21, 22, 23 are plate-shaped structure bodies with an area small than that of the heat conduction plates 11, 12, 13. The heat spreaders 21, 22, 23 can be made of graphite or the like material. The heat spreaders 21, 22, 23 have a property of quickly conducting heat along the surface (transversely). In this embodiment, the heat spreaders 21, 22, 23 are elongated plate bodies, each having a proximal-to-heat-source section 211, 221, 231 and a distal-from-heat-source section 212, 222, 232. The heat spreaders 21, 22, 23 and the heat conduction plates 11, 12, 13 are electrically bonded to each other by means of heat-conducting electroconductive adhesive layers 3.

In application, the contact face 111 of the heat conduction plate assembly 1 is in contact with a heat source 40. The proximal-to-heat-source section 211, 221, 231 of the heat spreaders 21, 22, 23 are closer to the heat source 40. In this embodiment, the heat source 40 is an electronic component arranged on a circuit board 4, (such as a processor, a power transistor, etc.) In addition, a heat-conducting adhesive 30 can be disposed between the heat source 40 and the contact face 111 to enhance the heat conduction effect.

In use, most of the heat generated by the heat source 40 passes through the heat-conducting adhesive 30 and is conducted from the contact face 111 to the heat conduction plate 11. The heat conduction plates 11, 12, 13 are plate-shaped bodies and made of metal material so that the heat conduction plates 11, 12, 13 are able to radially uniformly spread the heat at equal speed. Accordingly, the heat will very quickly pass through the heat conduction plate 11 and be transferred from the electroconductive adhesive layer 3 to the heat spreader 21. Due to the property of quickly conducting heat along the surface (transversely) of the heat spreader 21, the heat is quickly spread from the proximal-to-heat-source section 211 concentratively proximal to the heat source 40 to the distal-from-heat-source section 212 distal from the heat source 40. Then, the rest heat is conducted from the heat spreader 21 through the electroconductive adhesive layer 3 to the heat conduction plate 12, which dissipates part of the heat. The still rest heat passes through the electroconductive adhesive layer 3 and is transferred to the heat spreader 22, whereby the heat is again quickly transversely spread from the proximal-to-heat-source section 221 to the distal-from-heat-source section 222. The still rest heat passes through the electroconductive adhesive layer 3 and is transferred to the heat conduction plate 13, which dissipates part of the heat. Finally, all the rest heat passes through the electroconductive adhesive layer 3 and is transferred to the heat spreader 23, whereby the heat is again quickly transversely spread from the proximal-to-heat-source section 231 to the distal-from-heat-source section 232. Accordingly, thanks to the property of transversely complexly spreading heat of the heat spreaders 21, 22, 23 and the property of quickly directly outward dissipating heat of the heat conduction plates 11, 12, 13, the heat is effectively prevented from accumulating around the heat source 40. In this case, the temperature will not locally abnormally rise.

In this embodiment, the heat spreaders 21, 22 are respectively disposed between the heat conduction plates 11, 12, 13, while the heat spreader 23 is disposed on the other surface of the heat conduction plate 13. However, in practice, alternatively, the heat spreaders 22, 23 can be disposed between the heat conduction plates 11, 12, 13, while the heat spreader 21 is disposed on the contact face ill of the heat conduction plate 11 to form another type of assembly. In the case that the heat spreader 21 is disposed on the contact face 111 of the heat conduction plate 11, the contact face 111 and the heat spreader 21 are partially in contact with the heat source 40. (Heat-conducting adhesive 30 is also disposed between the heat source 40 and the adjacent heat conduction plate 11 and the heat spreader 21). Accordingly, a different type of assembly with the same effect is achieved. In addition, both the number of the heat conduction plates of the heat conduction plate assembly 1 and the number of the heat spreaders of the heat spreader assembly 2 can be increased or decreased as necessary to form different assemblies with different heat conduction and dissipation effects.

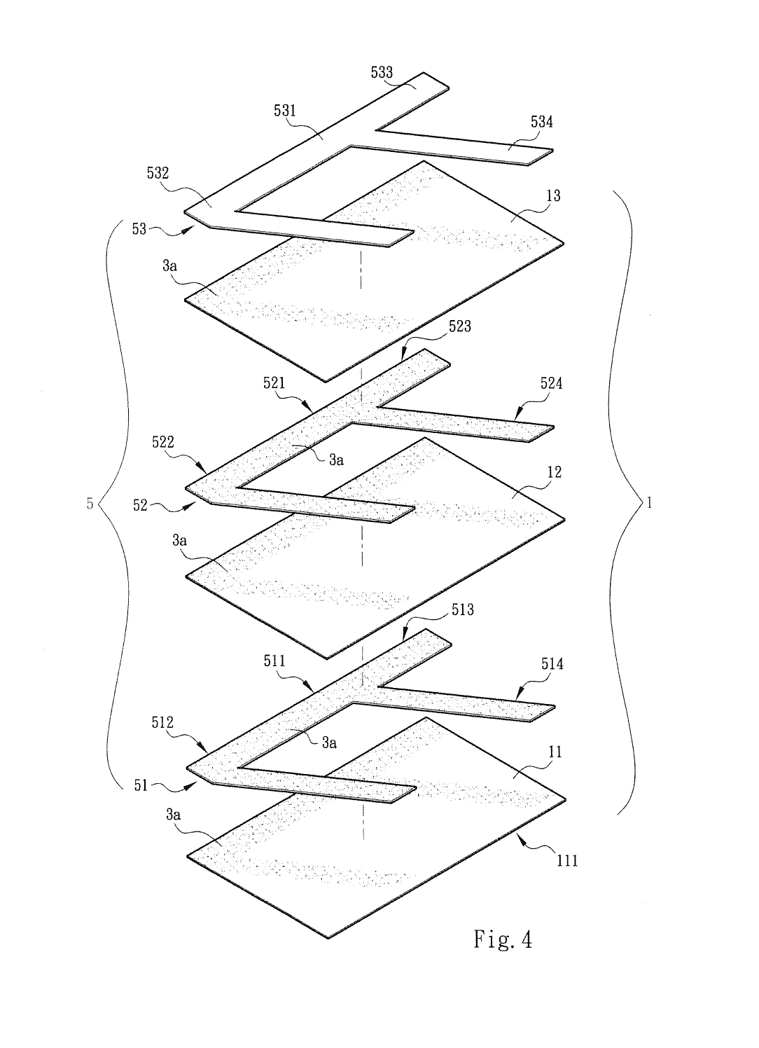

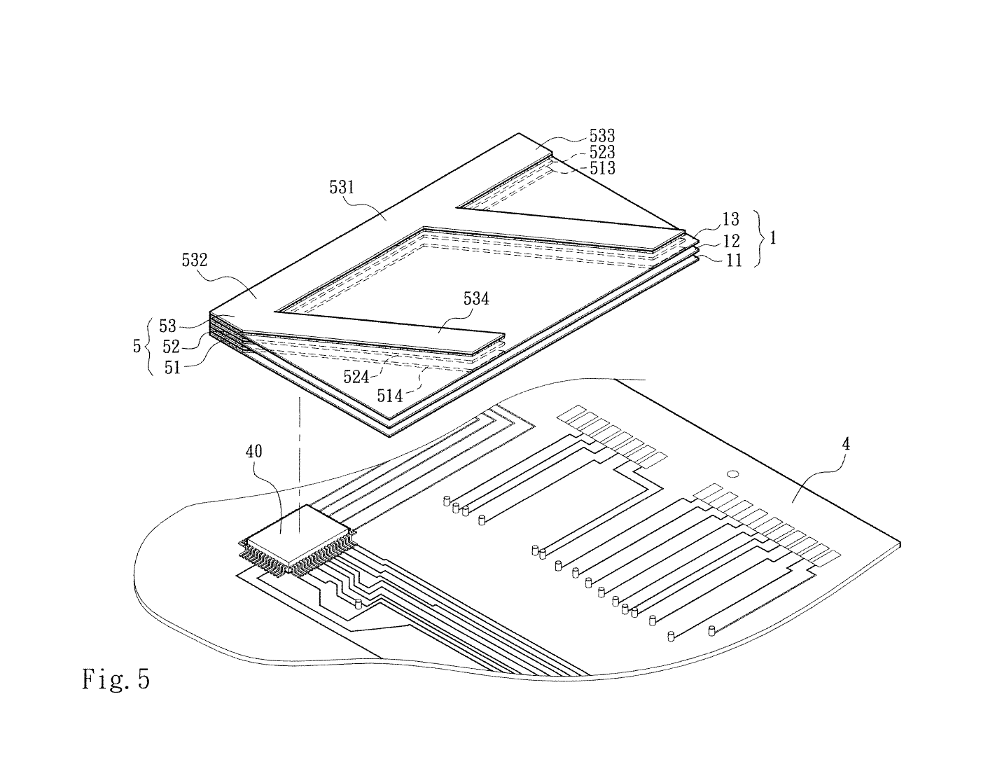

Please refer to FIGS. 4 and 5. According to a third embodiment, the complex heat dissipation assembly of the present invention includes a heat spreader assembly 5 and a heat conduction plate assembly 1 identical to that of the second embodiment. The heat conduction plate assembly 1 identically includes multiple heat conduction plates 11, 12, 13. The heat spreader assembly 5 is composed of multiple heat spreaders 51, 52, 53 respectively alternately disposed between the heat conduction plates 11, 12, 13. The heat spreaders 51, 52, 53 are plate-shaped structure bodies with an area small than that of the heat conduction plate assembly 1. The heat spreaders 51, 52, 53 can be made of graphite or the like material. The heat spreaders 51, 52, 53 have a property of quickly conducting heat along the surface (transversely). In this embodiment, each of the heat spreaders 51, 52, 53 has an elongated main extension section 511, 521, 531 and multiple branch sections 514, 524, 534 obliquely extending from one side of the main extension section 511, 521, 531 in parallel to each other. The branch sections 514, 524, 534 obliquely extend in a direction away from the heat source 40 and the main extension section 511, 521, 531. The main extension section 511, 521, 531 has a proximal-to-heat-source section 512, 522, 532 proximal to the heat source 40 and a distal-from-heat-source section 513, 523, 533 distal from the heat source 40. The heat spreaders 51, 52, 53 and the heat conduction plates 11, 12, 13 are electrically bonded to each other by means of heat-conducting electroconductive adhesive layers 3a.

In use, the heat generated by the heat source 40 passes through the heat-conducting adhesive 30 and is conducted from the contact face 111 to the heat conduction plate 11. Part of the heat is outward dissipated from the heat conduction plate 11. The rest heat quickly passes through the electroconductive adhesive layer 3a and is transferred to the heat spreader 51. Due to the property of quickly conducting heat along the surface (transversely) of the heat spreader 51, part of the heat is quickly spread from the proximal-to-heat-source section 512 of the main extension section 511 to the distal-from-heat-source section 513 of the main extension section 511. Also, the heat of the main extension section 511 is further transferred to the respective branch sections 514 to uniformly spread the heat. Then, the rest heat passes through the electroconductive adhesive layer 3a and is sequentially conducted to the heat conduction plate 12, the heat spreader 52, the heat conduction plate 13 and the heat spreader 53 to repeatedly dissipate the heat and transversely conduct the heat as the heat conduction plate 11 and the heat spreader 51. Accordingly, this embodiment can achieve the same effect as the first embodiment to prevent the heat from accumulating around the heat source 40. In this case, the temperature will not locally abnormally rise.

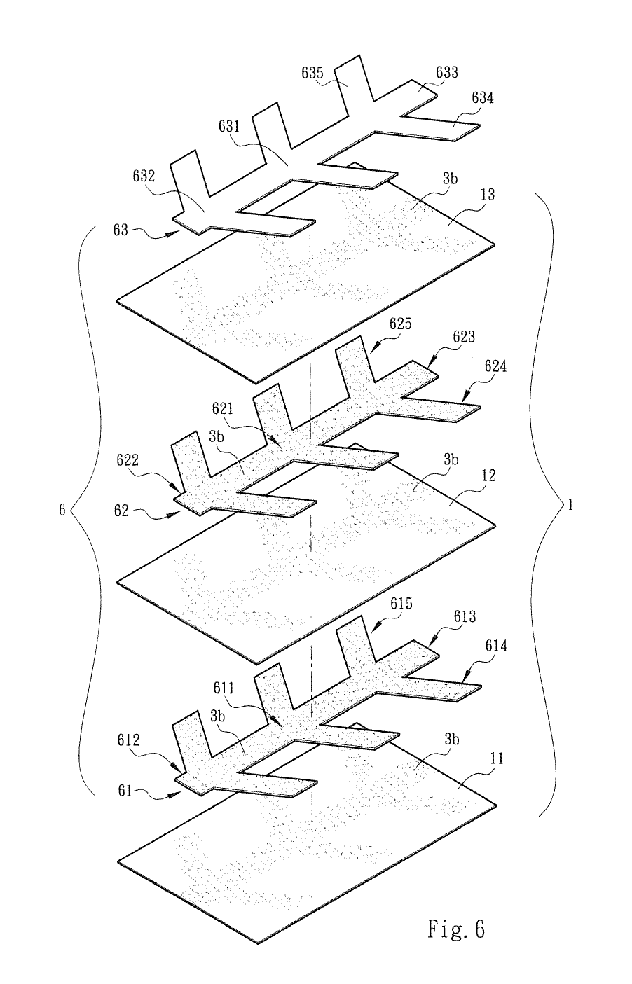

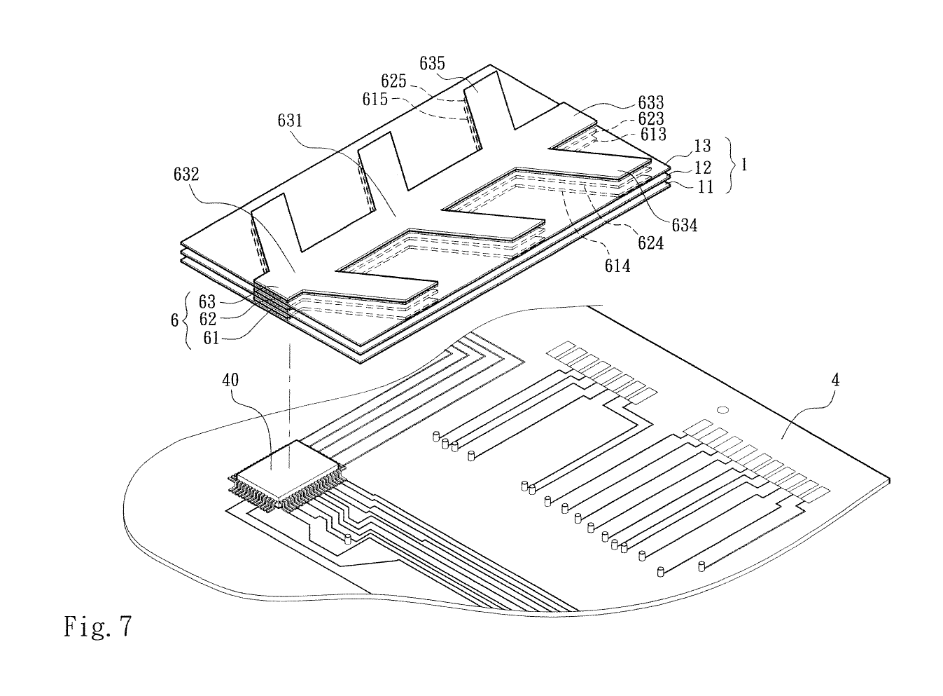

Please refer to FIGS. 6 and 7. According to a fourth embodiment, the complex heat dissipation assembly of the present invention includes a heat spreader assembly 6 and a heat conduction plate assembly 1 identical to that of the second embodiment. The heat conduction plate assembly 1 identically includes multiple heat conduction plates 11, 12, 13. The heat spreader assembly 6 is composed of multiple heat spreaders 61, 62, 63 respectively alternately disposed between the heat conduction plates 11, 12, 13. The heat spreaders 61, 62, 63 are plate-shaped structure bodies with an area small than that of the heat conduction plate assembly 1. The heat spreaders 51, 52, 53 can be made of graphite or the like material. The heat spreaders 51, 52, 53 have a property of quickly conducting heat along the surface (transversely). In this embodiment, each of the heat spreaders 61, 62, 63 has an elongated main extension section 611, 621, 631 and multiple branch sections 614, 615, 624, 625, 634, 635 obliquely extending from two sides of the main extension section 611, 621, 631 in parallel to each other. The branch sections 614, 615, 624, 625, 634, 635 obliquely extend in a direction away from the heat source 40 and the main extension section 611, 621, 631. The main extension section 611, 621, 631 has a proximal-to-heat-source section 612, 622, 632 proximal to the heat source 40 and a distal-from-heat-source section 613, 623, 633 distal from the heat source 40. The heat spreaders 61, 62, 63 and the heat conduction plates 11, 12, 13 are electrically bonded to each other by means of heat-conducting electroconductive adhesive layers 3b.

In use, the heat generated by the heat source 40 passes through the heat-conducting adhesive 30 and is conducted from the contact face 111 to the heat conduction plate 11. Part of the heat is outward dissipated from the heat conduction plate 11. The rest heat quickly passes through the electroconductive adhesive layer 3b and is transferred to the heat spreader 61. Due to the property of quickly conducting heat along the surface (transversely) of the heat spreader 61, part of the heat is quickly spread from the proximal-to-heat-source section 612 of the main extension section 611 to the distal-from-heat-source section 613 of the main extension section 611. Also, the heat of the main extension section 611 is further transferred to the respective branch sections 614, 615 to uniformly spread the heat. Then, the rest heat passes through the electroconductive adhesive layer 3b and is sequentially conducted to the heat conduction plate 12, the heat spreader 62, the heat conduction plate 13 and the heat spreader 63 to repeatedly dissipate the heat and transversely conduct the heat as the heat conduction plate 11 and the heat spreader 61. Accordingly, this embodiment can achieve the same effect as the first embodiment to prevent the heat from accumulating around the heat source 40. In this case, the temperature will not locally abnormally rise.

In conclusion, the complex heat dissipation assembly of the present invention is manufactured at lower cost and can quickly and uniformly transfer and dissipate the heat.

The above embodiments are only used to illustrate the present invention, not intended to limit the scope thereof. Many modifications of the above embodiments can be made without departing from the spirit of the present invention.

What is claimed is:

1. A complex heat dissipation assembly comprising:
a heat conduction plate assembly composed of multiple stacked electroconductive heat conduction plates; and
a heat spreader assembly composed of multiple heat spreaders, which are able to quickly conduct heat along the surface, the heat spreaders being alternately disposed between the heat conduction plates, each of the heat spreaders having a proximal-to-heat-source section proximal to a heat source and a distal-from-heat-source section extending in a direction away from the heat source, at least one of the heat conduction plate assembly and the heat spreader assembly being in contact with the heat source.

2. The complex heat dissipation assembly as claimed in claim 1, wherein each heat conduction plate has a heat spreader in adjacency to and corresponding to the heat conduction plate, the heat spreader being disposed on one face of the adjacent and corresponding heat conduction plate, which face is proximal to the heat source.

3. The complex heat dissipation assembly as claimed in claim 2, wherein both the heat conduction plate assembly and the heat spreader assembly are in contact with the heat source.

4. The complex heat dissipation assembly as claimed in claim 3, wherein heat-conducting adhesive is disposed between at least one of the heat conduction plate assembly and the heat spreader assembly and the heat source.

5. The complex heat dissipation assembly as claimed in claim 1, wherein each heat conduction plate has a heat spreader in adjacency to and corresponding to the heat conduction plate, the heat spreader being disposed on one face of the adjacent and corresponding heat conduction plate, which face is distal from the heat source.

6. The complex heat dissipation assembly as claimed in claim 5, wherein the heat conduction plate assembly is in contact with the heat source and the heat-conducting adhesive is disposed between the heat conduction plate assembly and the heat source.

7. The complex heat dissipation assembly as claimed in claim 1, wherein the heat spreaders have an area smaller than that of the heat conduction plate in contact with the heat spreaders.

8. The complex heat dissipation assembly as claimed in claim 2, wherein the heat spreaders have an area smaller than that of the heat conduction plate in contact with the heat spreaders.

9. The complex heat dissipation assembly as claimed in claim 3, wherein the heat spreaders have an area smaller than that of the heat conduction plate in contact with the heat spreaders.

10. The complex heat dissipation assembly as claimed in claim 5, wherein the heat spreaders have an area smaller than that of the heat conduction plate in contact with the heat spreaders.

11. The complex heat dissipation assembly as claimed in claim 7, wherein the heat spreaders are elongated plate bodies.

12. The complex heat dissipation assembly as claimed in claim 8, wherein the heat spreaders are elongated plate bodies.

13. The complex heat dissipation assembly as claimed in claim 10, wherein the heat spreaders are elongated plate bodies.

14. The complex heat dissipation assembly as claimed in claim 11, wherein each of the heat spreaders has an elongated main extension section and at least one branch section obliquely extending from one side of the main extension section.

15. The complex heat dissipation assembly as claimed in claim 12, wherein each of the heat spreaders has an elongated main extension section and at least one branch section obliquely extending from one side of the main extension section.

16. The complex heat dissipation assembly as claimed in claim 13, wherein each of the heat spreaders has an elongated main extension section and at least one branch section obliquely extending from one side of the main extension section.

17. The complex heat dissipation assembly as claimed in claim 14, wherein the branch section obliquely extends in a direction away from the heat source and the main extension section.

18. The complex heat dissipation assembly as claimed in claim 11, wherein each of the heat spreaders has an elongated main extension section and at least one branch section obliquely extending from each of two sides of the main extension section.

19. The complex heat dissipation assembly as claimed in claim 12, wherein each of the heat spreaders has an elongated main extension section and at least one branch section obliquely extending from each of two sides of the main extension section.

20. The complex heat dissipation assembly as claimed in claim 13, wherein each of the heat spreaders has an elongated main extension section and at least one branch section obliquely extending from each of two sides of the main extension section.

21. The complex heat dissipation assembly as claimed in claim 18, wherein the branch section obliquely extends in a direction away from the heat source and the main extension section.

22. The complex heat dissipation assembly as claimed in claim 1, wherein the heat spreaders have an area equal to that of the heat conduction plate in contact with the heat spreaders.

23. The complex heat dissipation assembly as claimed in claim 2, wherein the heat spreaders have an area equal to that of the heat conduction plate in contact with the heat spreaders.

24. The complex heat dissipation assembly as claimed in claim 3, wherein the heat spreaders have an area equal to that of the heat conduction plate in contact with the heat spreaders.

25. The complex heat dissipation assembly as claimed in claim 5, wherein the heat spreaders have an area equal to that of the heat conduction plate in contact with the heat spreaders.

26. The complex heat dissipation assembly as claimed in claim 1, wherein heat-conducting electroconductive adhesive layers are respectively disposed between the heat conduction plates and the heat spreaders.

27. The complex heat dissipation assembly as claimed in claim 2, wherein heat-conducting electroconductive adhesive layers are respectively disposed between the heat conduction plates and the heat spreaders.

28. The complex heat dissipation assembly as claimed in claim 3, wherein heat-conducting electroconductive adhesive layers are respectively disposed between the heat conduction plates and the heat spreaders.

29. The complex heat dissipation assembly as claimed in claim 5, wherein heat-conducting electroconductive adhesive layers are respectively disposed between the heat conduction plates and the heat spreaders.

30. The complex heat dissipation assembly as claimed in claim 7, wherein heat-conducting electroconductive adhesive layers are respectively disposed between the heat conduction plates and the heat spreaders.

31. The complex heat dissipation assembly as claimed in claim 14, wherein heat-conducting electroconductive adhesive layers are respectively disposed between the heat conduction plates and the heat spreaders.

32. The complex heat dissipation assembly as claimed in claim 18, wherein heat-conducting electroconductive adhesive layers are respectively disposed between the heat conduction plates and the heat spreaders.

33. The complex heat dissipation assembly as claimed in claim 22, wherein heat-conducting electroconductive adhesive layers are respectively disposed between the heat conduction plates and the heat spreaders.
